(19) United States
(12) Patent Application Publication
(10) Pub. No.: US 2014/0041911 A1
(43) Pub. Date: Feb. 13, 2014

(54) FLAT DAM AND METHOD FOR MANUFACTURING CHIP PACKAGE USING THE SAME

(71) Applicant: SAMSUNG ELECTRO-MECHANICS CO., LTD., Suwon (KR)

(72) Inventors: Chang Bo Lee, Suwon (KR); Chang Sup Ryu, Suwon (KR); Young Gwan Ko, Suwon (KR); Cheol Ho Choi, Suwon (KR)

(73) Assignee: SAMSUNG ELECTRO-MECHANICS CO., LTD., Suwon (KR)

(21) Appl. No.: 13/845,093

(22) Filed: Mar. 18, 2013

(30) Foreign Application Priority Data
Aug. 7, 2012 (KR) 10-2012-0086287

(51) Int. Cl. H01L 23/00

(52) U.S. Cl. CPC H01L 24/03; H01L 24/05
USPC 174/258; 438/121; 174/250

(57) ABSTRACT

Disclosed herein is a flat dam formed in a package region of an insulation layer provided on a board to limit movement of an underfill and made of the hydrophobic material including any one of or at least two of perfluorooctyl acrylate (PFAC), polypropylene, polytetrafluoroethylene (PTFE), and fluorine compound.

### CROSS REFERENCE TO RELATED APPLICATION

This application claims the benefit of Korean Patent Application No. 10-2012-0086287, filed on Aug. 7, 2012, entitled “Flat Dam and Method for Manufacturing Chip Package Using the Same”, which is hereby incorporated by reference in its entirety into this application.

### BACKGROUND OF THE INVENTION

1. Technical Field

The present invention relates to a flat dam and a method for manufacturing a chip package using the same.

2. Description of the Related Art

According to the prior art, as a pattern has been continuously fined in an electronic industry field, various technologies has been developed.

However, a packaging field is a field in which fine patterning is most slowly developed due to various difficulties caused by connection between a silicon chip and a substrate. Although there was significant achievements by application of a flip-chip technology substituted for the past wire bonding technology, it is still difficult to finely form a bump pattern.

In order to solve this problem, various researches are conducted. One of these recent researches is a method of forming a solder resist (SR) dam enclosing a region corresponding to a bump as disclosed in Korean Patent No. 10-0850763 (2008 Jul. 31).

The SR dam according to the prior art is formed to have a height by applying secondary SR to a portion on which a chip is mounted in order to serve to prevent flow of an underfill to allow a chip to be molded on a portion to be desired at the time of molding.

However, due to a demand of the SR dam having a thick thickness of 70 μm in a specification of a printed circuit board having a thin thickness of 15 μm or less in the prior art, a process of forming the SR dam according to the prior art causes various problems, for example, process defects such as product damage, curling, or the like, warpage, liquid contamination by an excessive amount of SR development, SR residue, or the like.

More specifically, according to the prior art, the SR is laminated on one surface of the printed circuit board to be provided with the dam, and an exposing process and a developing process are performed. In this case, when the thickness of the SR dam is thick, an ultra-thin printed circuit board itself causes the process defect while being warped or ripped during a process of laminating the SR on the ultra-thin printed circuit board, which is a cause of the warpage of the ultra-thin printed circuit board.

Further, in the case in which the SR dam is provided in a groove shape, some region of a circuit may be exposed according to a design of the printed circuit board. Therefore, a problem such as Galvanic corrosion may occur.

### SUMMARY OF THE INVENTION

The present invention has been made in an effort to provide a flat dam formed on a SR layer of a package region on which a chip is mounted.

The present invention has been also made in an effort to provide a method for manufacturing a chip package using a flat dam formed on an SR layer of a package region on which a chip is mounted to mount a chip.

According to a preferred embodiment of the present invention, there is provided a flat dam formed on a package region of an insulation layer provided on a board to limit movement of an underfill.

The flat dam may be formed in a surface of the insulation layer along an edge of the package region of the insulation layer.

The flat dam may be provided as a trench region, along an edge of the package region of the insulation layer, from an upper surface thereof to an inner portion thereof.

The flat dam may be further formed on a surface of the insulation layer between solder bumps provided in the package region.

The flat dam may be made of a hydrophobic material including any one or at least two of perfluorooctyl acrylate (PFAC), polypropylene, polytetrafluoroethylene (PTFE), and fluorine compound.

The flat dam may have an intermediate value between thermal expansion coefficient of the insulation layer and that of the underfill.

According to another preferred embodiment of the present invention, there is provided a method for manufacturing a chip package, including: (A) forming a plurality of circuit patterns on a board; (B) forming an insulation layer embedding the circuit pattern therein; (C) forming a flat dam on a package region of the insulation layer; (D) forming solder bumps on the package region; and (E) mounting a chip on the package region by an underfill process.

Step (A) may include: (A-1) laminating a dry film on an upper surface of the board; (A-2) performing a patterning process on the dry film to form a dry film pattern having a plurality of opening parts; (A-3) filling copper in the opening parts of the dry film pattern; and (A-4) peeling off the dry film pattern.

Step (A-3) may be performed by any one of a chemical vapor deposition (CVD) method, a physical vapor deposition (PVD) method, a subtractive method, an additive method using electroless copper plating or electro copper plating, a semi-additive process (SAP), and a modified semi-additive process (MSAP).

In step (C), the flat dam may be formed, along an edge of the package region, through surface modification of the surface of the insulation layer using a hydrophobic material.

In step (C), the flat dam may be formed by any one of an initiated chemical vapor deposition (iCVD) method, a CVD method, a PVD method, and a plasma polymerization method.

In step (C), the flat dam may be formed in a trench, along an edge of the package region, from an upper surface of the insulation layer to an inner portion thereof using a hydrophobic material.

In step (C), the hydrophobic material may be ionized to be implanted from the upper surface of the insulation layer to the inner portion thereof by an ion implantation method.

Flat dams may be further formed in the surface of the insulation layer between solder bumps to be provided in the package region.

The flat dam may have an intermediate value between thermal expansion coefficient of the insulation layer and that of the underfill.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view of a chip package according to a first preferred embodiment of the present invention;

FIG. 2 is a flow chart for describing a method for a manufacturing a chip package according to another preferred embodiment of the present invention;

FIG. 3 is an exemplary process diagram for describing an initiated chemical vapor deposition (iCVD) method among methods for forming a flat dam according to another preferred embodiment of the present invention;

FIG. 4 is an exemplary cross-sectional view for describing a method for forming a flat dam according to a second preferred embodiment of the present invention; and

FIG. 5 is an exemplary cross-sectional view for describing a method for forming a flat dam according to a third preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

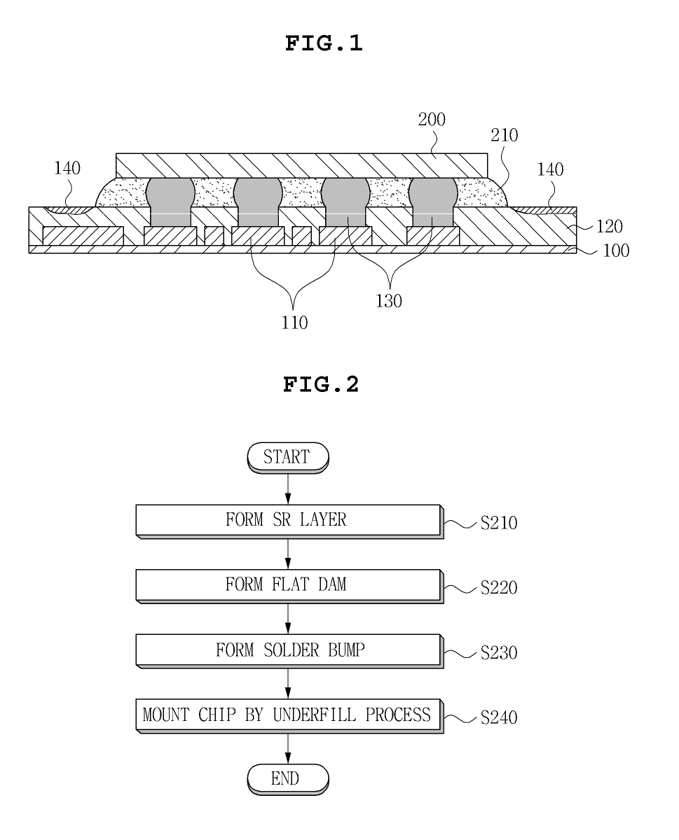

FIG. 1 is a cross-sectional view of a chip package according to a first preferred embodiment of the present invention.

The chip package according to the first preferred embodiment of the present invention is configured to include a board 100, a plurality of circuit patterns 110 provided on the board 100, solder bumps 130 contacting a pad of each circuit board 110 and attachedly connected to a chip 200, a solder resist (SR) pattern layer 120 enclosing the solder bumps 130 and embedding the circuit pattern 110 therein, an underfill 210 enclosing the solder bumps 130 between an upper surface of the SR pattern layer 120 and a lower surface of the chip 200, and a flat dam 140 formed on a package region of the SR pattern layer 120 enclosing the solder bumps 130 region to limit movement of the underfill 210.

The flat dam 140 is formed at a package region enclosing the solder bumps 130 along an upper portion of the SR pattern layer 120 or some region thereof, thereby preventing the underfill 210 from overflowing out of the package region in an underfill process for mounting the chip 200.

More specifically, the flat dam 140 may be formed along the upper surface of the SR to pattern layer 120 using a hydrophobic material, for example, perfluorooctyl acrylate (PFAC), polypropylene, polytetrafluoroethylene (PTFE), and a fluorine compound such as C₃F₆, or may be form as a trench-shaped region having a predetermined depth in the SR pattern layer 120.

This flat dam 140 may be formed by an initiated chemical vapor deposition (iCVD) method, a chemical vapor deposition (CVD) method, a physical vapor deposition (PVD) method such as a sputtering method, an ion implantation method, a plasma polymerization method, or the like.

The flat dam 140 as described above does not have polarity according to properties of the hydrophobic material, such that the flat dam 140 does not have affinity for a material of the underfill 210 on the time of contacting the underfill 210. Therefore, the underfill 210 does not overflow but contacts the flat dam 140 to thereby be lumped as shown in FIG. 1.

In addition, the flat dam 140 has an intermediate value between thermal expansion coefficient of the SR pattern layer 120 and that of the underfill 210, thereby making it possible to improve warpage resistance in a chip package.

Therefore, the entire thickness of the chip package according to the first preferred embodiment of the present invention may be reduced by forming the flat dam 140 on the upper surface of the package region of the SR pattern layer 120 rather than the SR dam in the art, and the overflow of the underfill 210 may be easily prevented.

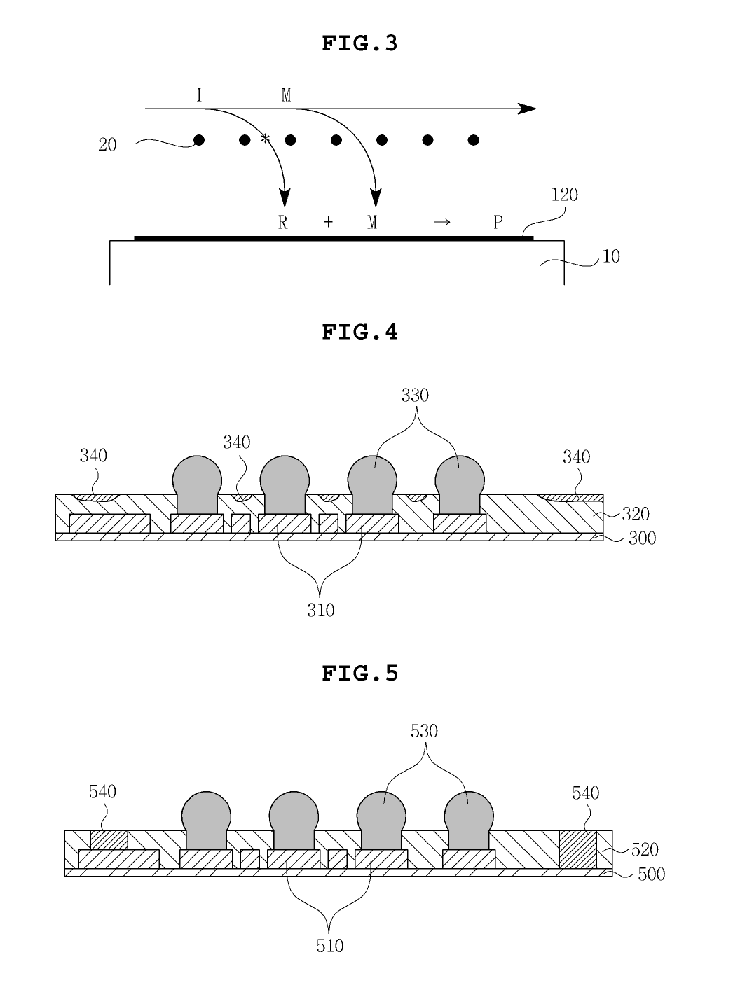

Hereinafter, a method for manufacturing a chip package according to the preferred embodiment of the present invention will be described with reference to FIGS. 2 to 5. FIG. 2 is a flow chart for describing a method for manufacturing a chip package according to another preferred embodiment of the present invention, FIG. 3 is an exemplary process diagram for describing an initiated chemical vapor deposition (iCVD) method among methods for forming a flat dam according to another preferred embodiment of the present invention, FIG. 4 is an exemplary cross-sectional view for describing a method for forming a flat dam according to a second preferred embodiment of the present invention, and FIG. 5 is an exemplary cross-sectional view for describing a method for forming a flat dam according to a third preferred embodiment of the present invention.

In the method for manufacturing a chip package according to another preferred embodiment of the present invention, first, a plurality of circuit patterns 110 are formed on a board 100 and an SR layer embedding the circuit pattern 110 therein is formed (S210).

More specifically, in the method for manufacturing a chip package according to another preferred embodiment of the present invention, first, a dry film is laminated on an upper surface of the board 100 and is processed with a patterning process including a lithography process, an etching process, and the like, such that a dry film pattern having opening parts may be formed.

The dry film pattern may be filled with copper by a CVD method, a PVD method, a subtractive method, an additive method using electroless copper plating or electro copper plating, a semi-additive process (SAP), a modified semi-additive process (MSAP), or the like, and then the dry film pattern may be peeled off.

Therefore, the circuit pattern 110 including a plurality of pads may be formed.

Then, a SR layer embedding the circuit pattern 110 therein is formed using a solder resist (SR).

After the SR layer is formed, a flat dam 140 is formed with respect to a package region on which a chip 200 is mounted (S220).

More specifically, the flat dam 140 may be formed on a surface along an edge of a package region of the SR layer using a hydrophobic material, for example, PFAC, polypropylene, PTFE, a fluorine compound, or the like, by an iCVD method, a CVD method, a PVD method such as a sputtering method, an ion implantation method, a plasma polymerization method, or the like.

Particularly, in the iCVD method, the flat dam 140 may be formed by a gas phase polymerization reaction of vaporizing a monomer M of a polymer forming a flat dam 140 in a chamber to simultaneously perform a polymerization process of the polymer and an evaporation process as shown in FIG. 3. In this iCVD method, an initiator I and the monomer M are vaporized to allow a polymerase chain reaction using a free radical R to be carried out in a gas phase, such that the flat dam 140 may be deposited on the surface of the SR layer.

When the initiator I and the monomer M are simply mixed, the polymerization reaction is not generated. However, when the initiator I is decomposed by a hot filament 20 positioned in an iCVD chamber to generate radical R, the monomer is activated by this radical, such that the polymerase chain reaction may be carried out.

As the initiator I, peroxide such as tert-butylperoxide (TBPO), tert-amyl peroxide, or the like, may be mainly used. This initiator I, which is a volatile material having a boiling point of about 110° C., is thermally decomposed at around 150° C.

Therefore, when a temperature of the hot filament 20 used in the iCVD chamber is maintained at around 200 to 250° C. the polymerase chain reaction may be easily induced. In this case, the temperature of the filament 20 is high enough to thermally decompose the initiator I of peroxide, but most of organic materials including the monomer M used in the iCVD method are not thermally decomposed at this temperature.

The free radical R formed by decomposition of the initiator I may transfer the radical R to the monomer M to cause a chain reaction, thereby making it possible to form the polymer P. The polymer P formed as described above may be deposited on a target such as a SR layer 120 on a stage 10 maintained at a low temperature to form the flat dam 140.

Therefore, the flat dam 140 may be provided along the edge of the package region of the SR layer through surface modification of the upper surface of the SR layer.

In this case, as flat dams 340 according to the second preferred embodiment of the present invention shown in FIG. 4, the flat dam 340 may be formed in the surface of the SR layer between solder bumps 330 to be formed later, in addition to the edge of the package region of the SR layer.

Alternatively, as a flat dam 540 according to the third preferred embodiment of the present invention as shown in FIG. 5, the flat dam 540 may be formed as a trench-shaped region having a predetermined depth from the upper surface of the SR layer to an inner portion thereof.

More specifically, in order to form the flat dam 540 according to the third preferred embodiment of the present invention shown in FIG. 5, a region of the flat dam 540 of the SR layer is etched to thereby be removed in a trench shape.

A hydrophobic material is filled in the trench formed as described above by an iCVD method, a CVD method, a PVD method, a plasma polymerization method, or the like.

After filling the trench with the hydrophobic material, a planarization process is performed on the SR layer including the trench filled with the hydrophobic material.

Therefore, the flat dam 540 having a flat upper surface may be provided on the SR layer.

On the other hand, the flat dam 540 may be more easily formed by an ion implantation method of implanting hydrophobic ions into the flat dam region 540 of the SR layer, in addition to the method of forming the trench.

Particularly, the flat dams 140, 340, or 540 are formed to have an intermediate value between thermal expansion coefficient of the SR layer and that of the underfill provided later, thereby making it possible to improve warpage resistance in a chip package.

As described above, after the flat dams 140, 340, or 540 having various shapes are formed, a plurality of solder dumps are formed with respect to the package region of the SR layer (S230).

First, in order to form solder bumps, a patterning process is performed on the SR layer exposing pads 110, 310, or 510 embedded in the SR layer.

The patterning process of the SR layer includes a lithography process, an etching process, and the like, the SR layer is formed as the SR pattern layer 120, 320, or 520 having opening parts corresponding to the pads 110, 310, and 510.

Then, the solder bumps 130, 330, or 530 are provided on the opening parts of the SR pattern layer 120, 320, or 520, respectively.

After the solder bumps 130, 330, or 530 are provided, the chip 200 is mounted on the board through the underfill and solder bumps 130, 330, or 530 by an underfill process (S240).

Here, the movement of the underfill made of a resin material and provided between a lower surface of the chip 200 and the upper surface of the SR pattern layer 120 is limited by the flat dam 140, 340, or 540 to thereby be cured without being out of the package region.

Therefore, in the method for manufacturing a chip package according to another embodiment of the present invention, the flat dam having a hydrophobic property is easily formed rather than the SR dam in the art to reduce the entire thickness of the package, such that the package capable of easily preventing the overflow of the underfill may be provided.

As set forth above, the entire thickness of the chip package according to the present invention may be reduced by the flat dam formed on the upper surface of the package region, rather than the SR dam in the art, and the overflow of the underfill may be easily prevented.

The chip package according to the present invention includes the flat dam having the intermediate value between thermal expansion coefficient of the SR pattern layer and that of the underfill, thereby making it possible to improve warpage resistance in the chip package.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A flat dam formed on a package region of an insulation layer provided on a board to limit movement of an underfill.

2. The flat dam as set forth in claim 1, wherein it is formed in a surface of the insulation layer along an edge of the package region of the insulation layer.

3. The flat dam as set forth in claim 1, wherein it is provided as a trench region, along an edge of the package region of the insulation layer, from an upper surface thereof to an inner portion thereof.

4. The flat dam as set forth in claim 2, wherein it is further formed in a surface of the insulation layer between solder bumps provided in the package region.

5. The flat dam as set forth in claim 1, wherein it is made of a hydrophobic material.

6. The flat dam as set forth in claim 5, wherein the hydrophobic material includes any one of or at least two of perfluorooctyl acrylate (PFAC), polypropylene, polytetrafluoroethylene (PTFE), and fluorine compound.

7. The flat dam as set forth in claim 1, wherein it has an intermediate value between thermal expansion coefficient of the insulation layer and that of the underfill.

8. A method for manufacturing a chip package, the method comprising:
(A) forming a plurality of circuit patterns on a board;
(B) forming an insulation layer embedding the circuit pattern therein;
(C) forming a flat dam on a package region of the insulation layer;
(D) forming solder bumps on the package region; and
(E) mounting a chip on the package region by an underfill process.

9. The method as set forth in claim 8, wherein step (A) includes:
(A-1) laminating a dry film on an upper surface of the board;
(A-2) performing a patterning process on the dry film to form a dry film pattern having a plurality of opening parts;
(A-3) filling copper in the opening parts of the dry film pattern; and
(A-4) peeling off the dry film pattern.

10. The method as set forth in claim 9, wherein step (A-3) is performed by any one of a chemical vapor deposition (CVD) method, a physical vapor deposition (PVD) method, a subtractive method, an additive method using electroless copper plating or electro copper plating, a semi-additive process (SAP), and a modified semi-additive process (MSAP).

11. The method as set forth in claim 8, wherein in step (C), the flat dam is formed, along an edge of the package region, through surface modification of the surface of the insulation layer using a hydrophobic material.

12. The method as set forth in claim 11, wherein in step (C), the flat dam is formed by any one of an initiated chemical vapor deposition (iCVD) method, a CVD method, a PVD method, and a plasma polymerization method.

13. The method as set forth in claim 8, wherein in step (C), the flat dam is formed in a trench shape, along an edge of the package region, from an upper surface of the insulation layer to an inner portion thereof using a hydrophobic material.

14. The method as set forth in claim 13, wherein in step (C), the hydrophobic material is ionized to be implanted from the upper surface of the insulation layer to the inner portion thereof by an ion implantation method.

15. The method as set forth in claim 11, wherein flat dams are further formed in the surface of the insulation layer between solder bumps to be provided in the package region.

16. The method as set forth in claim 8, wherein the flat dam has an intermediate value between thermal expansion coefficient of the insulation layer and that of the underfill.
